(19) United States
(12) Patent Application Publication
(10) Pub. No.: US 2014/0367149 A1
(43) Pub. Date: Dec. 18, 2014

(54) RESIN COMPOSITION FOR PRINTED CIRCUIT BOARD, BUILD-UP FILM, PREPREG AND PRINTED CIRCUIT BOARD

(71) Applicant: SAMSUNG ELECTRO-MECHANICS CO., LTD., Suwon (KR)

(72) Inventor: Jun Young Kim, Suwon (KR)

(73) Assignee: SAMSUNG ELECTRO-MECHANICS CO., LTD., Suwon (KR)

(21) Appl. No.: 14/078,126

(22) Filed: Nov. 12, 2013

(30) Foreign Application Priority Data
Jun. 14, 2013 (KR) 10-2013-0068350

(51) Int. Cl. H05K 1/03; C08J 5/18; H05K 3/28; C08K 3/36

(52) U.S. Cl. CPC H05K 1/0373; C08K 3/36; C08J 5/18; H05K 3/281; C08J 2383/06
USPC 174/255; 523/435; 427/387; 427/386; 156/60

(57) ABSTRACT

Disclosed herein are an insulating resin composition for a printed circuit board, a build-up film, a prepreg, and a printed circuit board. More specifically, disclosed herein are a build-up film prepared by using a resin composition containing a cage type silsesquioxane instead of the epoxy resin, and a multilayer printed circuit board including the build-up film or a prepreg.

### CROSS REFERENCE TO RELATED APPLICATION

This application claims the benefit of Korean Patent Application No. 10-2013-0068350, filed on Jun. 14, 2013, entitled “Resin Composition for Printed Circuit Board, Build-Up Film, Prepreg, and Printed Circuit Board” which is hereby incorporated by reference in its entirety into this application.

### BACKGROUND OF THE INVENTION

1. Technical Field

The present invention relates to a resin composition for a printed circuit board, a build-up film, a prepreg, and a printed circuit board.

2. Description of the Related Art

An epoxy resin to be used as an insulating material in a printed circuit board in the prior art has a coefficient of thermal expansion of about 40 to 80 ppm/° C. which is higher than that of a metal layer, and thus warpage or cracks on the interface may occur due to a difference of coefficients of thermal expansion at the time of being applied and adhered to the metal layer. Therefore, when the epoxy resin is used for a next-generation printed circuit board or packing materials requiring a very low change of dimension, the epoxy resin is generally combined with inorganic fillers or glass fabrics in order to improve thermal expansion properties of the epoxy resin. An example of improving a chemical structure of a resin itself in order to reduce a coefficient of thermal expansion before a combination includes an epoxy or biphenyl structure having a naphthalene core type structure or a fluorene core type structure in which intermolecular interaction (π-π Stacking) is easy, or a naphthalene based liquid crystal polymer. In a case of a naphthalene core type structure represented by the following Chemical Formulae a and b, a molecular structure which has not a curved shape but a straight and flat shape, reduces free volume of a major chain, increases packaging efficiency of a major chain, and intermolecular attraction to thereby improve a coefficient of thermal expansion, however, there is a limitation to implement a low coefficient of thermal expansion suitable for the printed circuit board by the resin alone.

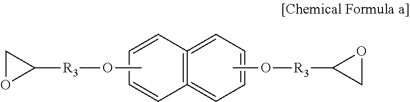

Herein, R₃ is an alkyl group having 1 to 10 carbon atoms.

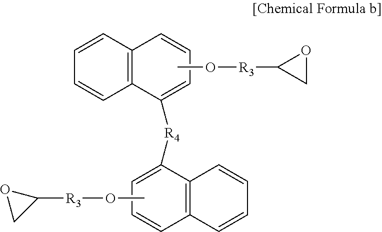

Herein, R₃ is an alkyl group having 1 to 10 carbon atoms and R₄ is a single bond or an alkyl group having 1 to 3 carbon atoms.

Therefore, inorganic fillers should be combined. In this case, a large amount of inorganic fillers being close to a charging limit thereof should be introduced into the complex. However, defects in chemical plating frequently occur due to a large number of the inorganic fillers, which are protruded from a surface layer during a desmear process at the time of being applied to a SAP printed circuit board.

Patent Document 1 discloses an epoxy resin composition including silsesquioxane. However, the silsesquioxane is used as a flame retardant aid and thus it is difficult to reduce a coefficient of thermal expansion of the resin itself.

### PRIOR ART DOCUMENT

### Patent Document

(Patent Document 1) Korean Patent Laid-Open Publication No. 2013-0018721 (WO 2011/108524)

### SUMMARY OF THE INVENTION

It is confirmed that as a resin composition for a printed circuit board, a product prepared using a resin composition including a cage type silsesquioxane, a curing agent, and an inorganic filler has a low coefficient of thermal expansion and a high glass transition temperature, and the present invention was completed based thereon.

Therefore, the present invention has been made in an effort to provide a resin composition for a printed circuit board having a low coefficient of thermal expansion and a high glass transition temperature.

Further, the present invention has been made in an effort to provide a built-up film having a low coefficient of thermal expansion and a high glass transition temperature, prepared by the resin composition.

Further, the present invention has been made in an effort to provide a prepreg prepared by impregnating a varnish containing the resin composition into an organic fiber or an inorganic fiber and drying the varnish thereon.

Further, the present invention has been made in an effort to provide a printed circuit board manufactured by stacking and laminating the build-up film on a circuit pattern-formed substrate.

Further, the present invention has been made in an effort to provide a multilayer printed circuit board manufactured by stacking copper foil on one surface or both surfaces of the prepreg to form a copper clad laminate (CCL), and laminating a build-up film thereon.

According to a preferred embodiment of the present invention, there is provided a resin composition for a printed circuit board, including: a cage type silsesquioxane; at least one curing agent selected from a group consisting of a phenol novolac curing agent, a triphenyl methane curing agent, and a biphenyl curing agent; and an inorganic filler.

A content of the cage type silsesquioxane may be 5 to 30 wt %, a content of the curing agent may be 5 to 35 wt %, and a content of the inorganic filler may be 45 to 85 wt %, based on 100 parts by weight of the resin composition.

The cage type silsesquioxane may be represented by the following Formula 1.

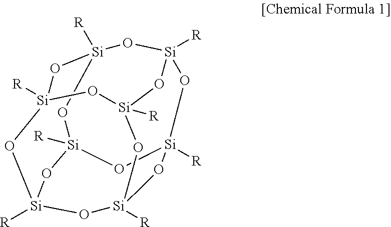

Herein, R's are the same as or different from each other, and may be hydrogen, an epoxy group, or an acrylate group in which the number of an epoxy group or an acrylate group is 4 to 8.

The cage type silsesquioxane may be a cage type silsesquioxane represented by the following Chemical Formulae 2 or 3 that R's of Chemical Formula 1 each are cyclohexyloxide or a glycidyl group.

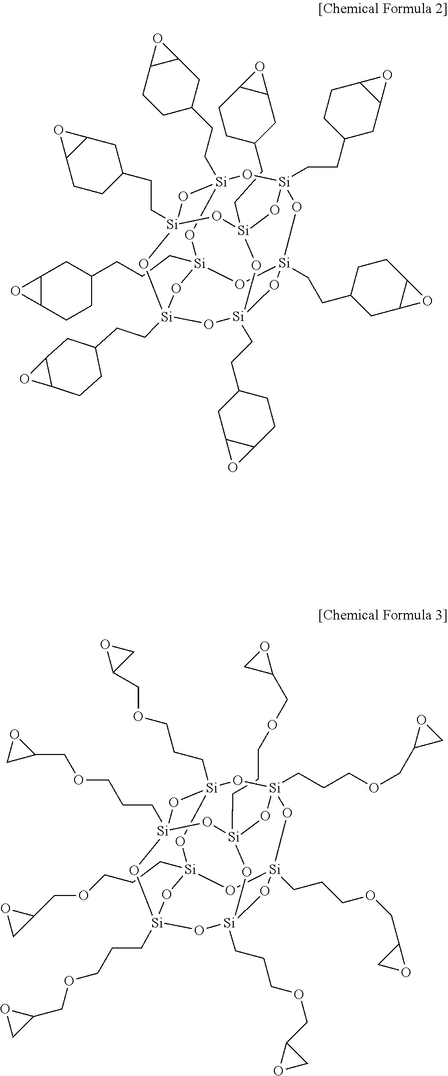 [SMILES: C(CC1CCC2OC2C1)C[Si]12O[Si]3(CCC4CCC5OC5C4)O[Si]4(CCC5CCC6OC6C5)O[Si](CCC5CCC6OC6C5)(O1)O[Si]1(CCC5CCC6OC6C5)O[Si](CCC5CCC6OC6C5)(O2)O[Si](CCC2CCC5OC5C2)(O3)O[Si](CCC2CCC3OC3C2)(O4)O1 ; C(COCC1CO1)C[Si]12O[Si]3(CCCOCC4CO4)O[Si]4(CCCOCC5CO5)O[Si](CCCOCC5CO5)(O1)O[Si]1(CCCOCC5CO5)O[Si](CCCOCC5CO5)(O2)O[Si](CCCOCC2CO2)(O3)O[Si](CCCOCC2CO2)(O4)O1]

The curing agent may be a biphenyl-based curing agent represented by the following Formula 4.

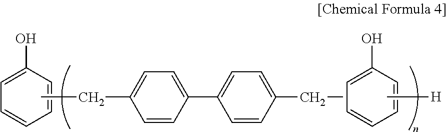

Herein, n is an integer of 1 to 5.

The inorganic filler may be at least one selected from a group consisting of natural silica, fused silica, amorphous silica, hollow silica, molybdenum oxide, zinc molybdate, alumina, talc, mica, and a glass single fiber.

The resin composition may further include 0.01 to 1 part(s) by weight of a curing accelerator, based on 100 parts by weight of the resin composition.

The curing accelerator may be at least one selected from a group consisting of a metal-based curing accelerator, an imidazole-based curing accelerator, and an amine based curing accelerator.

The resin composition may further include at least one additive selected from a group consisting of an ultraviolet absorber, an antioxidant, a photopolymerization initiator, a thickening agent, a lubricant, an antifoaming agent, a dispersant, a leveling agent, a polishing agent, and a silane coupling agent.

According to a preferred embodiment of the present invention, there is provided a build-up film prepared by applying and curing the resin composition as described above on a substrate.

According to a preferred embodiment of the present invention, there is provided a prepreg prepared by impregnating a varnish containing the resin composition as described above into an organic fiber or an inorganic fiber and drying the varnish thereon.

According to a preferred embodiment of the present invention, there is provided a printed circuit board manufactured by stacking and laminating the build-up film as described above on a circuit pattern-formed substrate.

According to a preferred embodiment of the present invention, there is provided a multilayer printed circuit board manufactured by laminating an insulating film on a copper clad laminate (CCL) obtained by stacking copper foil on one surface or both surfaces of the prepreg as described above.

### BRIEF DESCRIPTION OF THE DRAWINGS

The above and other objects, features, and advantages of the present invention will be more clearly understood from the following detailed description taken in conjunction with the accompanying drawings, in which:

FIG. 1 is a cross-sectional view of a general printed circuit board to which a resin composition according to a preferred embodiment of the present invention is applicable.

FIG. 2 is TMA results of insulating materials according to Examples 3 and 4 of the present invention.

### DESCRIPTION OF THE PREFERRED EMBODIMENTS

The objects, features and advantages of the present invention will be more clearly understood from the following detailed description of the preferred embodiments taken in conjunction with the accompanying drawings. Throughout the accompanying drawings, the same reference numerals are used to designate the same or similar components, and redundant descriptions thereof are omitted. Further, in the following description, the terms “first”, “second”, “one side”, “the other side” and the like are used to differentiate a certain component from other components, but the configuration of such components should not be construed to be limited by the terms. Further, in the description of the present invention, when it is determined that the detailed description of the related art would obscure the gist of the present invention, the description thereof will be omitted.

Hereinafter, preferred embodiments of the present invention will be described in detail with reference to the attached drawings.

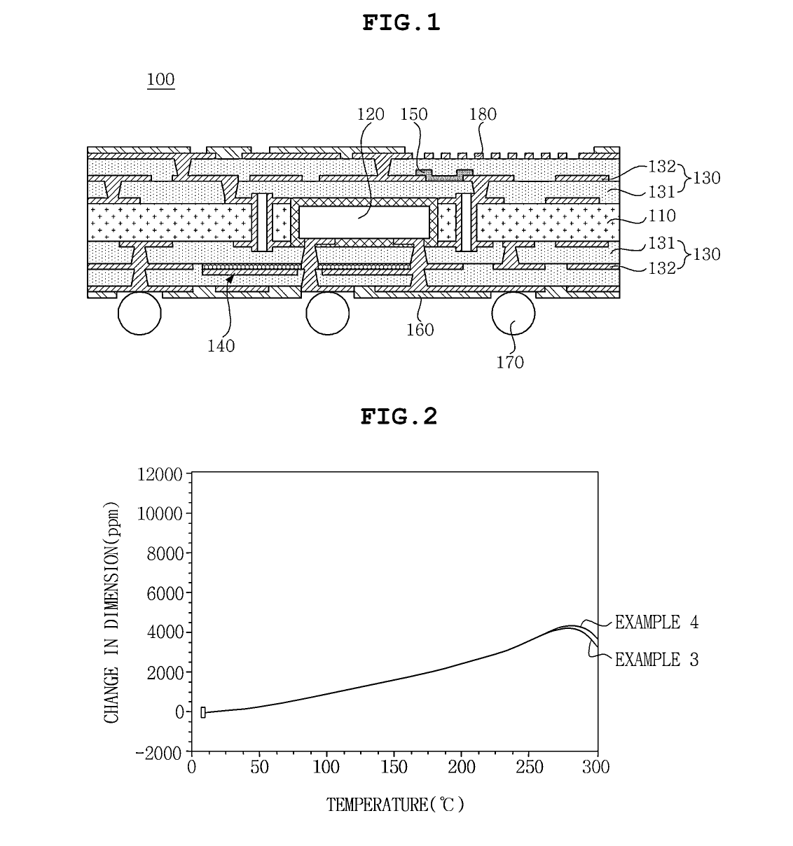

FIG. 1 is a cross-sectional view of a general printed circuit board to which a resin composition according to the present invention is applicable. Referring to FIG. 1, a printed circuit board 100 may be an embedded board into which electronic components are embedded. Specifically, the printed circuit board 100 may include an insulator 110 provided with a cavity, an electronic component 120 disposed in the cavity, and a build up layer 130 disposed on at least one of the upper surface and the lower surface of the insulator 110 including the electronic component 120. The build up layer 130 may include an insulating layer 131 disposed on at least one of the upper surface and the lower surface of the insulator 110, and a circuit layer 132 disposed on the insulating layer 131 and connected between the circuit layer 132 and the insulating layer 131. Herein, an example of the electronic component 120 may be an active element such as a semiconductor element. In addition, the printed circuit board 100 may not include one electronic component 120, but further may include at least one additional electronic component, for example, a capacitor 140 or a resistive element 150, which is not limited to kinds or numbers of the electronic components described in Examples of the present invention. Further, the outermost layer is provided with a solder resist layer 160 for protecting the circuit board. The printed circuit board may be provided with an external connection unit 170 depending on electronic products to be mounted thereon, and may be provided with a pad layer 180 in some cases. Herein, the insulator 110 and the insulating layer 131 may serve to provide an insulating property between the circuit layers or between electronic components, and serve as a structure to maintain the rigidity of a package. In this case, when a wiring density of the printed circuit board 100 is increased, in order to reduce noise between the circuit layers and to simultaneously reduce a parasitic capacitance, the insulator 110 and the insulating layer 131 require a low dielectric constant property. In addition, in order to improve an insulating property, the insulator 110 and the insulating layer 131 require a low dielectric loss property. As described above, at least one of the insulator 110 and the insulating layer 131 should have rigidity, while reducing a dielectric constant and a dielectric loss. According to the present invention, in order to secure the rigidity of the printed circuit board by decreasing coefficient of thermal expansion of the insulating layer and increasing a glass transition temperature and a storage modulus thereof, the insulating layer 131 and the insulator 110 may be formed of the insulating resin composition for a printed circuit board including a cage type silsesquioxane; a curing agent; and an inorganic filler.

Cage Type Silsesquioxane

A general resin which has been used in the prior art is an epoxy resin. However, since a coefficient of thermal expansion of an epoxy resin itself is not suitable for serving as an insulating layer of a printed circuit board, the epoxy resin is added with an inorganic filler or a glass fiber, or the like so as to reduce the coefficient of thermal expansion. However, since a large number of inorganic fillers are exposed on the surface by a desmear process, an adhesion peel strength with the metal layer may be reduced.

Therefore, when the cage type silsesquioxane is used, instead of the epoxy resin which has been used as an insulating layer material of a printed circuit board in the prior art, a coefficient of thermal expansion of the resin itself is reduced, an inorganic filler is filled without exceeding a charge limit thereof, such that a defect in adhesion to the metal layer during the desmear process may be solved.

The cage type silsesquioxane according to a preferred embodiment of the present invention may be present in a liquid state due to a low molecular weight and be formed of a matrix of a thermosetting complex, which is represented by the following Formula 1.

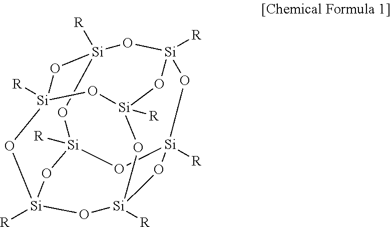

Herein, R's are the same as or different from each other, and may be hydrogen, an epoxy group, or an acrylate group in which the number of epoxy groups or acrylate groups is 4 to 8.

R of Chemical Formula 1 may be an epoxy group or an acrylate group in a curve shape. According to the present invention, the cage type silsesquioxane is preferably a cage type silsesquioxane represented by the following Chemical Formulae 2 or 3 that R's of Chemical Formula 1 each are cyclohexyloxide or a glycidyl group.

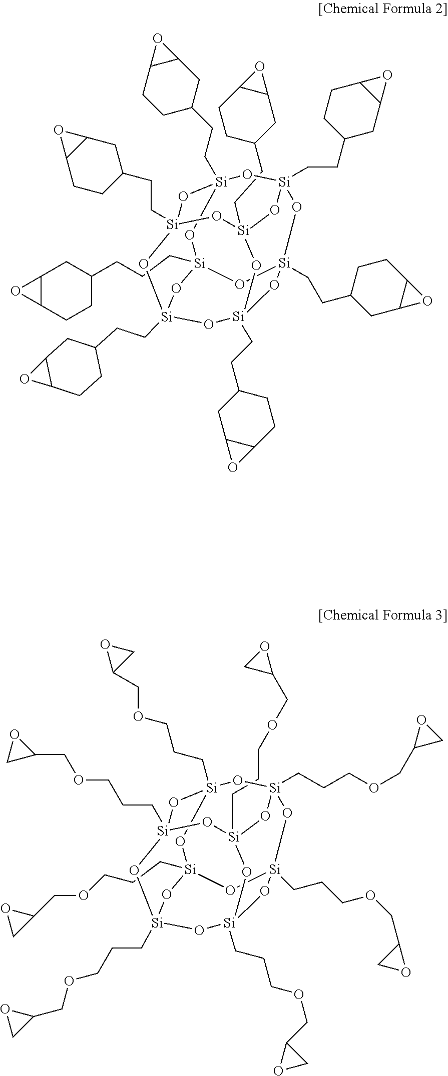 [SMILES: C(CC1CCC2OC2C1)C[Si]12O[Si]3(CCC4CCC5OC5C4)O[Si]4(CCC5CCC6OC6C5)O[Si](CCC5CCC6OC6C5)(O1)O[Si]1(CCC5CCC6OC6C5)O[Si](CCC5CCC6OC6C5)(O2)O[Si](CCC2CCC5OC5C2)(O3)O[Si](CCC2CCC3OC3C2)(O4)O1 ; C(COCC1CO1)C[Si]12O[Si]3(CCCOCC4CO4)O[Si]4(CCCOCC5CO5)O[Si](CCCOCC5CO5)(O1)O[Si]1(CCCOCC5CO5)O[Si](CCCOCC5CO5)(O2)O[Si](CCCOCC2CO2)(O3)O[Si](CCCOCC2CO2)(O4)O1]

A cured product is obtained by using the cage-type silsesquioxane as a resin, of which the surface can be made appropriately coarse during a desmear step of an SAP printed circuit board processes. Due to the reduced content of the inorganic filler, erosion caused by desmear chemicals is significantly reduced and thus it is easy to control defects in a chemical plating.

Further, when R's of Chemical Formula 1 have four or more epoxy groups or acrylate groups, it was found that a coefficient of thermal expansion of the curing material is lowered up to 30 ppm/° C. or less without adding an inorganic filler. In the prior art, a large number of inorganic fillers having a low coefficient of thermal expansion should be added in order to reduce a high coefficient of thermal expansion of epoxy resin or acrylate resin. Whereas, the cage type silsesquioxane according to a preferred embodiment of the present invention is structurally the same as a unit cubic structure of the inorganic filler, silica (SiO₂), so that it has a very low coefficient of thermal expansion, and therefore the content of the inorganic filler may be reduced significantly.

The amount of cage type silsesquioxane to be used in the present invention is 5 to 30 wt %, and preferably 10 to 25 wt %. When the amount of cage silsesquioxane to be used is less than 5 wt %, the amount of curing agent to be reacted is reduced so that it tends to increase a coefficient of thermal expansion. When the amount is more than 30 wt %, non-curing cage type silsesquioxane may interfere with polymerization of materials.

Curing Agent

The curing agent according to a preferred embodiment of the present invention may be at least one selected from a group consisting of a phenol novolac curing agent, a triphenyl methane curing agent, and a biphenyl curing agent, and preferably a biphenyl-based curing agent. The biphenyl-based curing agent represented by the following Chemical Formula 4 may be cured with a functional group of the cage type silsesquioxane. Further, the curing agent preferably contains the same equivalent as an epoxy equivalent of the cage type silsesquioxane. In order to improve a curing density, the curing agent may be used up to about 1.2 times of epoxy equivalent of the cage type silsesquioxane, if necessary.

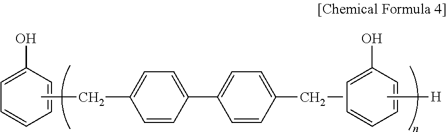

Herein, n is an integer of 1 to 5.

An amount of curing agent to be used in the resin composition is not specifically limited, but is preferably 5 to 35 wt %, and more preferably 10 to 30 wt %. When the amount of curing agent to be used is less than 5 wt %, a curing density may be decreased. When the amount is more than 35 wt %, it may interfere with polymerization of materials.

Inorganic Filler

The resin composition according to a preferred embodiment of the present invention may include an inorganic filler in order to reduce a coefficient of thermal expansion of the resin composition. Specific examples of the inorganic filler to be used for the present invention may include at least one selected from a group consisting of natural silica, fused silica, amorphous silica, hollow silica, molybdenum oxide, zinc molybdate, alumina, talc, mica, and a glass single fiber. They may be used singly or in combination of two or more kinds thereof. The inorganic filler preferably has a particle diameter having a specific surface area of 10 m²/g or more.

The inorganic filler, which reduces a coefficient of thermal expansion, has the content of the inorganic filler to the resin composition varied depending on the required properties in view of use of the resin composition, preferably 45 to 85 wt %, and more preferably 50 to 70 wt %. When the content of the inorganic filler is less than 45 wt %, a coefficient of thermal expansion may be increased. When the content of the inorganic filler is more than 85 wt %, processability of a laser drill may be deteriorated.

Further, the inorganic filler may be singly added to the resin composition, but may be preferable to be added with a silane coupling agent or a wetting dispersing agent in combination in order to improve dispersibility and adhesion between resins. The silane coupling agent is not specifically limited so long as it may be generally used for the surface treatment of inorganic materials, and preferably γ-glycidoxypropyltrimethoxysilane.

Curing Accelerator

The resin composition according to a preferred embodiment of the present invention may be cured efficiently by selectively containing the curing accelerator therein. The curing accelerator to be used for the present invention may include a metal-based curing accelerator, an imidazole-based curing accelerator, and an amine-based curing accelerator, and the curing accelerators may be used singly or in combination of two or more kinds thereof.

An amount of curing accelerator to be used in the resin composition is not specifically limited, but is preferably 0.01 to 1 part(s) by weight based on 100 parts by weight of the resin composition.

The metal-based curing accelerator is not specifically limited, but may include an organic metal complex or an organic metal salt of metal such as cobalt, copper, zinc, iron, nickel, manganese, and tin. Specific examples of the organic metal complex may include an organic cobalt complex such as cobalt (II) acetylacetonate, or cobalt (III) acetylacetonate, an organic copper complex such as copper (II) acetylacetonate, an organic zinc complex such as zinc (II) acetylacetonate, an organic iron complex such as iron (III) acetylacetonate, an organic nickel complex such as nickel (II) acetylacetonate, or an organic manganese complex such as manganese (II) acetylacetonate. Examples of the organic metal salt may include zinc octylate, tin octylate, zinc naphthenate, cobalt naphthenate, tin stearate, zinc stearate, and the like. From the viewpoint of a curing property and solvent solubility, the metal-based curing accelerator may be preferably cobalt (II) acetyl acetonate, cobalt (III) acetylacetonate, zinc (II) acetylacetonate, zinc naphthenate, iron (III) acetylacetonate, and more preferably, cobalt (II) acetylacetonate or zinc naphthenate. The metal-based curing accelerators may be used singly or in combination of two or more kinds thereof.

Examples of the imidazole-based curing accelerator are not specifically limited, but may include imidazole compounds such as 2-methyl imidazole, 2-undecyl imidazole, 2-heptadecyl imidazole, 1,2-dimethyl imidazole, 2-ethyl-4-methyl imidazole, 1,2-dimethyl imidazole, 2-ethyl-4-methyl imidazole, 2-phenyl imidazole, 2-phenyl-4-methyl imidazole, 1-benzyl-2-methyl imidazole, 1-benzyl-2-phenyl imidazole, 1-cyanoethyl-2-methyl imidazole, 1-cyanoethyl-2-undecyl imidazole, 1-cyanoethyl-2-ethyl-4-methyl imidazole, 1-cyanoethyl-2-phenyl imidazole, 1-cyanoethyl-2-undecyl imidazolium trimellitate, 1-cyanoethyl-2-phenyl imidazolium trimellitate, 2,4-diamino-6-[2′-methyl imidazolyl-(1′)]ethyl-s-triazine, 2,4-diamino-6-[2′-undecyl imidazolyl-(1′)]ethyl-s-triazine, 2,4-diamino-6[2′-ethyl-4′-methyl imidazolyl-(1′)]ethyl-s-triazine, 2,4-diamino-6-[2′-methyl imidazolyl-(1′)]-ethyl-s-triazineisocyanuric adduct, 2-phenylimidazol isocyanuric adduct, 2-phenyl-4,5-dihydroxylmethylimidazole, 2-phenyl-4-methyl-5-hydroxymethylimidazole, 2,3-dihydroxy-1H-pyrrolo[1,2-a]benzimidazole, 1-dodecyl-2-methyl-3-benzylimidazolium chloride, 2-methyl imidazoline, and 2-phenyl imidazoline, and additive of the imidazole compound and the epoxy resin. The imidazole-based curing accelerators may be used singly or in combination of two or more kinds.

Examples of the amine-based curing accelerator are not specifically limited, but may include trialkyl amine such as triethyl amine or tributyl amine, amine compound such as 4-dimethylaminopyridine, benzyldimethylamine, 2,4,6-tris(dimethylaminomethyl)phenol, and 1,8-dizabicyclo(5,4,0)-undecene (hereinafter, referred to as DBU), and the like. The amine-based curing accelerators may be used singly or in combination of two or more kinds thereof.

Additives

The resin composition according to a preferred embodiment of the present invention may selectively include additives so long as it does not deteriorate mechanical properties. Examples of the additive may include polymer compounds such as a thermoplastic resin and a thermosetting resin, an ultraviolet absorber, an antioxidant, a photopolymerization initiator, a thickening agent, a lubricant, an antifoaming agent, a dispersant, a leveling agent, a polishing agent, and a silane coupling agent, and the like.

Examples of the thermoplastic resin may include a phenoxy resin, a polyimide resin, a polyamideimide (PAI) resin, a polyetherimide (PEI) resin, a polysulfone (PS) resin, a polyethersulfone (PES) resin, a polyphenylene ether (PPE) resin, a polycarbonate (PC) resin, a polyetheretherketone (PEEK) resin, and a polyester resin, and the like.

The resin composition according to a preferred embodiment of the present invention may be prepared in a semi-solid film form, according to general methods known in the art. For example, the composition is formed in the film by using a roll coater, or a curtain coater, is dried, and then is applied on the board to thereby be used as the insulating layer (or insulating film) or the prepreg upon the preparation of a multilayer printed board by a build-up scheme. The build-up film or the prepreg may have a low coefficient of thermal expansion (CTE) and a high glass transition temperature (Tg).

As described above, with the resin composition according to a preferred embodiment of the present invention, a varnish containing the resin composition is impregnated into a base material such as an organic fiber or an inorganic fiber, and then cured to prepare a prepreg, and a copper foil is stacked on the prepreg to thereby obtain a copper clad laminate (CCL). Further, the build-up film prepared by the resin composition according to a preferred embodiment of the present invention is laminated on a CCL to be used as an inner layer at the time of manufacturing a multilayer printed circuit board, which is used for manufacturing the multilayer printed circuit board. For example, the build-up film prepared by the resin composition is laminated on the inner layer circuit board being processed in a pattern, cured at a temperature of 80 to 110° C. for 20 to 30 minutes, subjected to a desmear process to form a circuit layer through an electric plating process, and thus a multilayer printed circuit board may be manufactured.

The inorganic fiber is a glass fiber, and examples of the glass fiber include a carbon fiber, a polyparaphenylene benzobisoxazole fiber, a thermotropic liquid crystal polymer fiber, a lyotropic liquid crystal polymer fiber, an aramide fiber, a polypiridobisimidazole fiber, a polybenzothiazole fiber, and a polyarylate. The inorganic fibers may be used singly or in combination of two or more kinds thereof.

The present invention will be described in more detail with reference to Examples and Comparative Examples, but the scope of the present invention is not limited to the following examples.

### Preparation of Resin Composition

### Example 1

177 g of cage type silsesquioxane (EP0408 manufactured by Hybrid Plastics, Inc.) in which R's are replaced by eight cyclohexyloxides was mixed with a dispersion liquid where 312.5 g of a silica having a particle size of about 0.1 μm was dispersed in a methyl ethyl ketone (MEK) solvent, was pre-dispersed using a bead mill, to obtain a composition, the composition was dissolved in 205 g of a biphenyl curing agent (GPH-103, manufactured by Nippon Kataku Co., Ltd.), 6.83 g of 2-ethyl-4-methylimidazole was added thereto to prepare a resin composition.

### Example 2

177 g of cage type silsesquioxane (EPO408 manufactured by Hybrid Plastics, Inc.) in which R's are replaced by eight cyclohexyloxides was mixed with a dispersion liquid where 230.7 g of a silica having a particle size of about 0.1 μm was dispersed in a methyl ethyl ketone (MEK) solvent, was pre-dispersed using a bead mill, to obtain a composition, the composition was dissolved in 105 g of a phenol novolac curing agent, 5.127 g of 2-ethyl-4-methylimidazole was added thereto to prepare a resin composition.

### Comparative Example 1

167 g of naphthalene type 4 functional epoxy resin (HP-4700 manufactured by DIC) was mixed with a dispersion liquid where 222.5 g of a silica having a particle size of about 0.1 μm was dispersed in a methyl ethyl ketone (MEK) solvent, was pre-dispersed using a bead mill, to obtain an organic and inorganic complex, the organic and inorganic complex was dissolved in 105 g of a phenol novolac curing agent (TD-2092) having the same equivalent, 4.945 g of 2-ethyl-4-methylimidazole was added thereto to prepare a resin composition.

### Preparation of Build-Up Film

### Example 3

A PET surface having release force was subjected to a hand-casting such that the resin composition prepared by Example 1 has a thickness of about 30 μm, followed by drying at 70° C. for 10 minutes in an oven to prepare a film.

### Example 4

A film was prepared using the resin composition prepared by Example 2 under the same conditions as in Example 3.

### Comparative Example 2

A film was prepared using the resin composition prepared by Comparative Example 1 under the same conditions as in Example 3.

The film prepared through Examples 3 and 4 and Comparative Example 2 was laminated on a copper clad laminate, followed by thermosetting in an oven at 180° C. for 1 hour. The copper surface was etched with nitric acid (HNO₃), to prepare a specimen having a length of 24 mm and a width of 5 mm. Subsequently, a coefficient of thermal expansion was measured by a thermomechanical analyzer (TMA Q400, manufactured by TA Instruments Inc.) and a glass transition temperature was measured by a dynamic mechanical analyzer (DMA Q800, manufactured by TA Instruments). Results were shown in Table 1.

TABLE 1

| | Coefficient of thermal | Glass transition temperature |
|---|---|---|
| | expansion (CTE) | (Tg) |
| Example 3 | 17 ppm/° C. | 170° C. |
| Example 4 | 28 ppm/° C. | 168° C. |
| Comparative Example 2 | 40 ppm/° C. | 155° C. |

As shown in Table 1, it was confirmed that the coefficients of thermal expansion of the films in Examples 3 and 4 prepared using the resin composition containing the cage type silsesquioxane according to a preferred embodiment of the present invention were lower than that of the film in Comparative Example 2 prepared by using the epoxy resin used in the prior art. Also, it was believed that the glass transition temperature was increased.

As set forth above, with the resin composition for a printed circuit board according to the present invention, the build-up film, the prepreg, and the printed circuit board prepared by using the resin composition containing the cage type silsesquioxane, instead of an epoxy resin, can have a low coefficient of thermal expansion and a high glass transition temperature.

Although the embodiments of the present invention have been disclosed for illustrative purposes, it will be appreciated that the present invention is not limited thereto, and those skilled in the art will appreciate that various modifications, additions and substitutions are possible, without departing from the scope and spirit of the invention.

Accordingly, any and all modifications, variations or equivalent arrangements should be considered to be within the scope of the invention, and the detailed scope of the invention will be disclosed by the accompanying claims.

What is claimed is:

1. A resin composition for a printed circuit board, comprising:
a cage type silsesquioxane;
at least one curing agent selected from a group consisting of a phenol novolac curing agent, a triphenyl methane-based curing agent, and a biphenyl-based curing agent; and
an inorganic filler.

2. The resin composition for a printed circuit board as set forth in claim 1, wherein a content of the cage type silsesquioxane is 5 to 30 wt %, a content of the curing agent is 5 to 35 wt %, and a content of the inorganic filler is 45 to 85 wt %, based on 100 parts by weight of the resin composition.

3. The resin composition for a printed circuit board as set forth in claim 1, wherein the cage type silsesquioxane is represented by the following Formula 1: 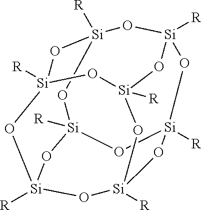
wherein, R's are the same as or different from each other, and are hydrogen, an epoxy group, or an acrylate group, in which the number of the epoxy group or the acrylate group is 4 to 8.

4. The resin composition for a printed circuit board as set forth in claim 3, wherein the cage type silsesquioxane is the cage type silsesquioxane represented by the following Chemical Formulae 2 or 3 that R's of Chemical Formula 1 each are cyclohexyloxide or a glycidyl group:

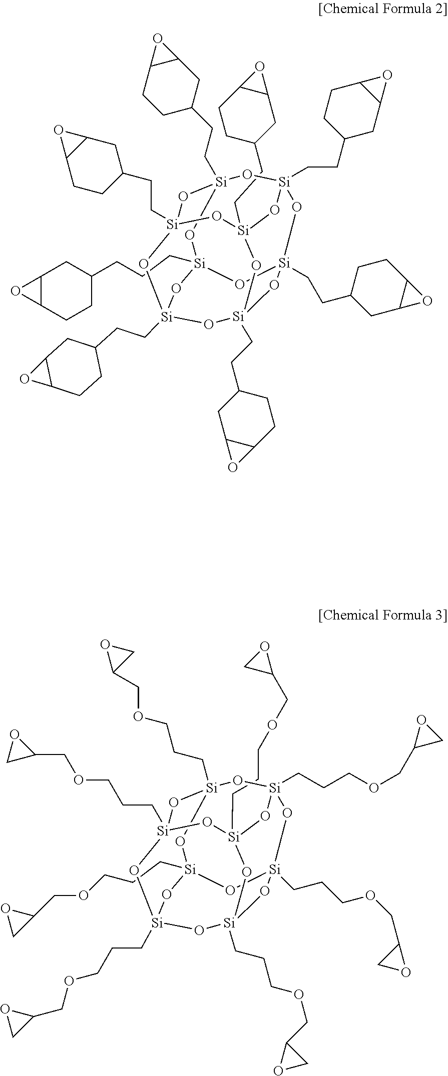 [SMILES: C(CC1CCC2OC2C1)C[Si]12O[Si]3(CCC4CCC5OC5C4)O[Si]4(CCC5CCC6OC6C5)O[Si](CCC5CCC6OC6C5)(O1)O[Si]1(CCC5CCC6OC6C5)O[Si](CCC5CCC6OC6C5)(O2)O[Si](CCC2CCC5OC5C2)(O3)O[Si](CCC2CCC3OC3C2)(O4)O1 ; C(COCC1CO1)C[Si]12O[Si]3(CCCOCC4CO4)O[Si]4(CCCOCC5CO5)O[Si](CCCOCC5CO5)(O1)O[Si]1(CCCOCC5CO5)O[Si](CCCOCC5CO5)(O2)O[Si](CCCOCC2CO2)(O3)O[Si](CCCOCC2CO2)(O4)O1]

5. The resin composition for a printed circuit board as set forth in claim 1, wherein the curing agent is a biphenyl-based curing agent represented by the following Formula 4: 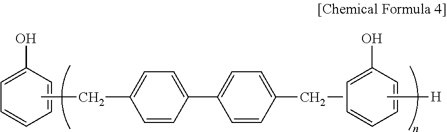
wherein, n is an integer of 1 to 5.

6. The resin composition for a printed circuit board as set forth in claim 1, wherein the inorganic filler is at least one selected from a group consisting of natural silica, fused silica, amorphous silica, hollow silica, molybdenum oxide, zinc molybdate, alumina, talc, mica, and a glass single fiber.

7. The resin composition for a printed circuit board as set forth in claim 1, further comprising 0.01 to 1 part(s) by weight of a curing accelerator, based on 100 parts by weight of the resin composition.

8. The resin composition for a printed circuit board as set forth in claim 7, wherein the curing accelerator is at least one selected from a group consisting of a metal-based curing accelerator, an imidazole-based curing accelerator, and an amine based curing accelerator.

9. The resin composition for a printed circuit board as set forth in claim 1, further comprising at least one additive selected from a group consisting of an ultraviolet absorber, an antioxidant, a photopolymerization initiator, a thickening agent, a lubricant, an antifoaming agent, a dispersant, a leveling agent, a polishing agent, and a silane coupling agent.

10. A build-up film prepared by applying and curing the resin composition as set forth in claim 1 on a substrate.

11. A prepreg prepared by impregnating a varnish containing the resin composition as set forth in claim 1 into an organic fiber or an inorganic fiber and drying the varnish thereon.

12. A printed circuit board manufactured by stacking and laminating the build-up film as set forth in claim 10 on a circuit pattern-formed substrate.

13. A multilayer printed circuit board manufactured by laminating an insulating film on a copper clad laminate (CCL) obtained by stacking copper foil on one surface or both surfaces of the prepreg as set forth in claim 11.
